(19) United States
(12) Patent Application Publication
(10) Pub. No.: US 2025/0071962 A1
(43) Pub. Date: Feb. 27, 2025

(54) BOND HEAD HAVING INDIVIDUALLY-DISPLACEABLE BOND ARMS

(71) Applicant: ASMPT Singapore Pte. Ltd., Singapore (SG)

(72) Inventors: Chi Wah CHENG, Hong Kong SAR (CN); Hok Man WAN, Hong Kong SAR (CN); Tze Ki Tony LEUNG, Hong Kong SAR (CN)

(21) Appl. No.: 18/456,040

(22) Filed: Aug. 25, 2023

(51) Int. Cl. H05K 13/04

(52) U.S. Cl. CPC H05K 13/041; H05K 13/0406

(57) ABSTRACT

A method of transferring a plurality of electronic devices with a bond head mechanism having a bond head having a plurality of individually-displaceable bond arms includes the steps of: in a pickup operation, moving the bond head mechanism to position a first bond arm of the bond head mechanism over a first electronic device from a group of electronic devices from a supply of electronic devices arranged in a pickup area, and actuating only the first bond arm to pick up the first electronic device from the group of electronic devices; and moving the bond head to position a second bond arm of the bond head over a second electronic device from the group of electronic devices, and actuating only the second bond arm of the bond head to pick up the second electronic device.

### FIELD OF THE INVENTION

The invention relates to a method and apparatus for transferring a plurality of electronic devices with a bond head mechanism having a bond head including a plurality of individually-displaceable bond arms.

### BACKGROUND

The processing of electronic devices such as dies, chips or other such components can require an apparatus to be provided that has a bond head mechanism for the pickup, transfer and placement of those objects at a bonding station for bonding. For example, a die may be picked up by the bond head mechanism, assisted by an ejector if required, and transferred to a bonding location on a substrate such as a lead frame bond pad on a work holder at the bonding station. As throughput requirements increase, the operational performance of the processing needs to be correspondingly increased.

However, some problems may be encountered when seeking to improve the performance of the processing.

It would be beneficial to provide an arrangement to improve performance arrangement as compared to the prior art.

### SUMMARY OF THE INVENTION

It is thus an object of this invention to seek to provide a method and/or apparatus which overcomes at least some of the aforementioned problems of the prior art.

According to a first aspect of the present invention, there is provided a method of transferring a plurality of electronic devices with a bond head mechanism having a bond head having a plurality of individually-displaceable bond arms, comprising: in a pickup operation, moving the bond head mechanism to position a first bond arm of the bond head mechanism over a first electronic device from a group of electronic devices from a supply of electronic devices arranged in a pickup area, and actuating only the first bond arm to pick up the first electronic device from the group of electronic devices; and moving the bond head to position a second bond arm of the bond head over a second electronic device from the group of electronic devices, and actuating only the second bond arm of the bond head to pick up the second electronic device.

The first aspect recognizes that a problem with improving the performance of processing electronic devices is that the throughput can be limited by the distances over which the electronic devices need to be transferred and the speed of operation of the bond head mechanism. In particular, changing the layout by reducing a pick-to-bond distance will cause interference between any ejector, wafer table and work holder. Also, increasing bond head moving speed is problematic as the movement speed is restricted by hardware limitations such as encoder performance, linear motion guide and module rigidity. Moreover, increasing the motion speed will cause a shorter life-time of the linear motion guide and signal loss of the encoder. Accordingly, a method is provided. The method may be a method of transferring a plurality of electronic devices, packages or dies with a bond head mechanism. The bond head mechanism may have a bond head. The bond head may have a plurality of individually-displaceable bond arms. The method may comprise, in a pickup operation, moving the bond head mechanism to position a first bond arm of the bond head mechanism over a first electronic device from a group or set of electronic devices from a supply or source of electronic devices arranged in a pickup area. The method may comprise actuating only or just the first bond arm to pick up the first electronic device from the group of electronic devices. The method may comprise moving the bond head to position a second bond arm of the bond head over a second electronic device from the group of electronic devices. The method may comprise actuating only or just the second bond arm of the bond head to pick up the second electronic device. In this way, multiple electronic devices may be picked up by the same bond head which increases the number of electronic devices that can be transferred and increases the throughput.

The method may comprise, during the pickup operation, moving the bond head to position a subsequent bond arm of the bond head over a subsequent electronic device from the group of electronic devices. The method may comprise actuating only the subsequent bond arm of the bond head to pick up the subsequent electronic device from the group of electronic devices.

The method may comprise, during the pickup operation, moving the bond head to position a third bond arm of the bond head over a third electronic device from the group of electronic devices. The method may comprise actuating only the third bond arm of the bond head to pick up the third electronic device from the group of electronic devices.

The method may comprise, during the pickup operation, moving the bond head to position a fourth bond arm of the bond head over a fourth electronic device from the group of electronic devices. The method may comprise actuating only the fourth bond arm of the bond head to pick up the fourth electronic device from the group of electronic devices.

Each bond arm of the bond head may comprise an individual actuator configured to displace that bond arm in directions towards and away from the group of electronic devices. The method may comprise activating the individual actuator associated with that bond arm to displace only that bond arm towards the group of electronic devices to engage with a respective electronic device and then away from the group of electronic devices to pick up that electronic device. Hence, single bond arms may be displaced individually, one at a time. This enables individual electronic devices to be picked up rather than needing the whole group to be picked up together. This can be helpful when the electronic devices to be picked up are adhered to an adhesive substrate and allows the pitch between electronic devices and between bond arms to differ.

The method may comprise activating the individual actuator associated with that bond arm to displace only that bond arm between a retracted position spaced from the group of electronic devices and an extended position in contact with the respective electronic device to be picked up.

The method may comprise, during the pickup operation, sequentially moving the group of electronic devices to locate each electronic device from the group of electronic devices over an ejector pin and displacing the ejector pin to facilitate pickup of that electronic device by a respective bond arm. Hence, the same ejector pin can be reused to assist in the pickup of the electronic devices.

The second bond arm of the bond head may be adjacent the first bond arm of the bond head.

The second electronic device may be adjacent the first electronic device in the group of electronic devices.

The first electronic device may be arranged adjacent to the second electronic device along a row of electronic devices.

The bond arms of the bond head may be sequentially adjacent each other.

The method may comprise, in a placement operation, moving the bond head to position the first bond arm of the bond head over a bonding location within a first section of a substrate at a bonding station. The method may comprise actuating just the first bond arm of the bond head to place the first electronic device of the group of electronic devices at the bonding location within the first section of the substrate. Hence, the bond head with the picked up electronic devices may be moved together to the bonding location. Also, single bond arms may be displaced individually, one at a time. This enables individual electronic devices to be placed rather than needing the whole group to be placed up together. This also allows the pitch between bonding locations and between bond arms to differ.

The method may comprise, during the placement operation, subsequently moving the bond head to position the second bond arm of the bond head over a bonding location within a second section of the substrate. The method may comprise actuating only the second bond arm of the bond head to place the second electronic device of the group of electronic devices at the bonding location within the second section of the substrate.

The method may comprise, during the placement operation, subsequently moving the bond head to position a subsequent bond arm of the bond head over a bonding location within a subsequent section of the substrate. The method may comprise actuating only the subsequent bond arm of the bond head to place the subsequent electronic device of the group of electronic devices at the bonding location within the subsequent section of the substrate.

The method may comprise, during the placement operation, subsequently moving the bond head to position the third bond arm of the bond head over a bonding location within a third section of the substrate. The method may comprise actuating only the third bond arm of the bond head to place the third electronic device of the group of electronic devices at the bonding location within the third section of the substrate.

The method may comprise, during the placement operation, subsequently moving the bond head to position the fourth bond arm of the bond head over a bonding location within a fourth section of the substrate. The method may comprise, actuating only the fourth bond arm of the bond head to place the fourth electronic device of the group of electronic devices at the bonding location within the fourth section of the substrate.

The bond head may comprise or be a first bond head. The bond head mechanism may further comprise a second or additional bond head separate from the first bond head. In other words, the bond head may comprise a plurality of bond heads. The second bond head may have a plurality of individually-displaceable bond arms. The group of electronic devices may comprises a first group of electronic devices. The method may further comprise, in a pick and place operation, moving the second bond head to position a first bond arm of the second bond head over a first electronic device from a second group of electronic devices. The method may comprise actuating only the first bond arm of the second bond head to pick up the first electronic device from the second group of electronic devices. The method may comprise moving the first bond head to position the first bond arm of the first bond head over a first bonding location within a first section of a substrate at a bonding station. The substrate may be divided into multiple sections of bonding locations. The method may comprise actuating only the first bond arm of the first bond head to place the first electronic device from the first group of electronic devices at the first bonding location within the first section of the substrate. Hence, two bond head may be provided. One bond head may place an electronic device while the other bond head picks up an electronic device. This helps to increase the throughput.

The method may comprise, during the pick and place operation, subsequently moving the second bond head to position a second bond arm of the second bond head over a second electronic device from the second group of electronic devices. The method may comprise actuating only the second bond arm of the second bond head to pick up the second electronic device from the second group of electronic devices. The method may comprise subsequently moving the first bond head to position the second bond arm of the first bond head over a first bonding location within a second section of the substrate. The method may comprise actuating only the second bond arm of the first bond head to place the second electronic device from the first group of electronic devices at the first bonding location within the second section of the substrate.

The method may comprise, during the pick and place operation, subsequently moving the second bond head to position a subsequent bond arm of the second bond head over a subsequent electronic device from the second group of electronic devices. The method may comprise actuating only the subsequent bond arm of the second bond head to pick up the subsequent electronic device from the second group of electronic devices. The method may comprise subsequently moving the first bond head to position a subsequent bond arm of the first bond head over a first bonding location within a subsequent section of the substrate. The method may comprise actuating only the subsequent bond arm of the first bond head to place the subsequent electronic device from the first group of electronic devices at the first bonding location within the subsequent section of the substrate.

The method may comprise, during the pick and place operation, subsequently moving the second bond head to position a third bond arm of the second bond head over a third electronic device from the second group of electronic devices. The method may comprise actuating only the third bond arm of the second bond head to pick up the third electronic device from the second group of electronic devices. The method may comprise subsequently moving the first bond head to position the third bond arm of the first bond head over a first bonding location within a third section of the substrate. The method may comprise actuating only the third bond arm of the first bond head to place the third electronic device from the first group of electronic devices at the first bonding location within the third section of the substrate.

The method may comprise, during the pick and place operation, subsequently moving the second bond head to position a fourth bond arm of the second bond head over a fourth electronic device from the second group of electronic devices. The method may comprise actuating only the fourth bond arm of the second bond head to pick up the fourth electronic device from the second group of electronic devices. The method may comprise subsequently moving the first bond head to position the fourth bond arm of the first bond head over a first bonding location within a fourth section of the substrate. The method may comprise actuating only the fourth bond arm of the first bond head to place the fourth electronic device from the first group of electronic devices at the first bonding location within the fourth section of the substrate.

Each pickup with the second bond head may occur simultaneously or concurrently with each placement with the first bond head.

The second bond arm of the second bond head may be adjacent the first bond arm of the second bond head.

The second electronic device of the second group of electronic devices may be adjacent the first electronic device of the second group of electronic devices.

Successive sections of the substrate may be contiguous with each other.

Each subsequent section containing bonding locations may be adjacent a preceding section containing bonding locations.

The method may comprise, in a placement operation, moving the second bond head to position the first bond arm of the second bond head over a second bonding location within the first section of the substrate. The method may comprise actuating just the first bond arm of the second bond head to place the first electronic device of the second group of electronic devices at the second bonding location within the first section of the substrate.

The method may comprise, during the placement operation, subsequently moving the second bond head to position the second bond arm of the second bond head over a second bonding location within the second section of the substrate. The method may comprise actuating only the second bond arm of the second bond head to place the second electronic device of the second group of electronic devices at the second bonding location within the second section of the substrate.

The method may comprise, during the placement operation, subsequently moving the second bond head to position a subsequent bond arm of the second bond head over a subsequent bonding location within the third section of the substrate. The method may comprise actuating only the subsequent bond arm of the second bond head to place the subsequent electronic device of the second group of electronic devices at the second bonding location within the subsequent section of the substrate.

The method may comprise, during the placement operation, subsequently moving the second bond head to position the third bond arm of the second bond head over a second bonding location within the third section of the substrate. The method may comprise actuating only the third bond arm of the second bond head to place the third electronic device of the second group of electronic devices at the second bonding location within the third section of the substrate.

The method may comprise, during the placement operation, subsequently moving the second bond head to position the fourth bond arm of the second bond head over a second bonding location within the fourth section of the substrate. The method may comprise actuating only the fourth bond arm of the second bond head to place the fourth electronic device of the second group of electronic devices at the second bonding location within the fourth section of the substrate.

The first bond head and the second bond head may share a common positioning mechanism for positioning the first and second bond heads along orthogonal X and Y axes, the first and second bond heads being movable together along the X axis but independently along the Y axis between different pickup and/or placement positions.

According to a second aspect of the present invention, there is provided an apparatus configured to perform the method according to the first aspect of the present invention.

According to a second aspect of the present invention, there is provided an apparatus for transferring a plurality of electronic devices, comprising: a bond head mechanism having a plurality of individually-displaceable bond arms, the apparatus being operable in a pickup operation to position a first bond arm of the plurality of individually-displaceable bond arms over a first electronic device from a group of electronic devices in a pickup area and to actuate only the first bond arm to pick up the first electronic device from the group of electronic devices and to position a second bond arm of the plurality of individually-displaceable bond arms over a second electronic device from the group of electronic devices and to actuate only the second bond arm to pick up the second electronic device from the group of electronic devices.

The apparatus may be operable to position a third bond arm of the plurality of individually-displaceable bond arms over a third electronic device from the group of electronic devices and to actuate only the third bond arm of the bond head to pick up the third electronic device from the group of electronic devices.

The apparatus may be operable to position a fourth bond arm of the plurality of individually-displaceable bond arms over a fourth electronic device from the group of electronic devices and to actuate only the fourth bond arm of the bond head to pick up the fourth electronic device from the group of electronic devices.

Each bond arm of the bond head may comprise an individual actuator configured to displace that bond arm in directions towards and away from the group of electronic devices and the bond head mechanism may be operable to activate the individual actuator associated with that bond arm to displace only that bond arm towards the group of electronic devices to engage with a respective electronic device and then away from the group of electronic devices to pick up that electronic device.

The bond head mechanism may be operable to activate the individual actuator associated with that bond arm to displace only that bond arm between a retracted position spaced from the group of electronic devices and an extended position in contact with the respective electronic device to be picked up.

The apparatus may comprise an ejector pin and a mechanism configured to sequentially move the group of electronic devices to locate each electronic device from the group of electronic devices over the ejector pin. The apparatus may be operable to displace the ejector pin to facilitate pickup of that electronic device by a respective bond arm.

The second bond arm of the bond head may be adjacent the first bond arm of the bond head.

The second electronic device may be adjacent the first electronic device in the group of electronic devices.

The first electronic device may be arranged adjacent to the second electronic device along a row of electronic devices.

The apparatus may be operable in a placement operation to move the bond head to position the first bond arm of the bond head over a bonding location within a first section of a substrate at a bonding station and to actuate just the first bond arm of the bond head to place the first electronic device of the group of electronic devices at the bonding location within the first section of the substrate.

The apparatus may be operable to subsequently move the bond head to position the second bond arm of the bond head over a bonding location within a second section of the substrate and to actuate only the second bond arm of the bond head to place the second electronic device of the group of electronic devices at the bonding location within the second section of the substrate.

The apparatus may be operable to subsequently move the bond head to position the third bond arm of the bond head over a bonding location within a third section of the substrate and actuating only the third bond arm of the bond head to place the third electronic device of the group of electronic devices at the bonding location within the third section of the substrate.

The apparatus may be operable to subsequently move the bond head to position the fourth bond arm of the bond head over a bonding location within a fourth section of the substrate and actuating only the fourth bond arm of the bond head to place the fourth electronic device of the group of electronic devices at the bonding location within the fourth section of the substrate.

The bond head may comprise a first bond head. The bond head mechanism may further comprises a second bond head separate from the first bond head. The second bond head may have a plurality of individually-displaceable bond arms. The group of electronic devices may comprise a first group of electronic devices. The apparatus may be operable in a pick and place operation to move the second bond head to position a first bond arm of the second bond head over a first electronic device from a second group of electronic devices and to actuate only the first bond arm of the second bond head to pick up the first electronic device from the second group of electronic devices and to move the first bond head to position the first bond arm of the first bond head over a first bonding location within a first section of a substrate at a bonding station. The substrate may be divided into multiple sections of bonding locations. The apparatus may be operable to actuate only the first bond arm of the first bond head to place the first electronic device from the first group of electronic devices at the first bonding location within the first section of the substrate.

The apparatus may be operable to subsequently move the second bond head to position a second bond arm of the second bond head over a second electronic device from the second group of electronic devices and to actuate only the second bond arm of the second bond head to pick up the second electronic device from the second group of electronic devices and to subsequently move the first bond head to position the second bond arm of the first bond head over a first bonding location within a second section of the substrate and to actuate only the second bond arm of the first bond head to place the second electronic device from the first group of electronic devices at the first bonding location within the second section of the substrate.

The apparatus may be operable to subsequently move the second bond head to position a third bond arm of the second bond head over a third electronic device from the second group of electronic devices and actuating only the third bond arm of the second bond head to pick up the third electronic device from the second group of electronic devices and to subsequently move the first bond head to position the third bond arm of the first bond head over a first bonding location within a third section of the substrate and to actuate only the third bond arm of the first bond head to place the subsequent electronic device from the first group of electronic devices at the first bonding location within the third section of the substrate.

The apparatus may be operable to subsequently move the second bond head to position a fourth bond arm of the second bond head over a fourth electronic device from the second group of electronic devices and to actuate only the fourth bond arm of the second bond head to pick up the fourth electronic device from the second group of electronic devices and to subsequently move the first bond head to position the fourth bond arm of the first bond head over a first bonding location within a fourth section of the substrate and to actuate only the fourth bond arm of the first bond head to place the fourth electronic device from the first group of electronic devices at the first bonding location within the fourth section of the substrate.

The apparatus may be operable so that each pickup with the second bond head occurs simultaneously with each placement with the first bond head.

The second bond arm of the second bond head may be adjacent the first bond arm of the second bond head.

The second electronic device of the second group of electronic devices may be adjacent the first electronic device of the second group of electronic devices.

Successive sections of the substrate may be contiguous with each other.

Each subsequent section may contain bonding locations is adjacent a preceding section containing bonding locations.

The apparatus may be operable in a placement operation to move the second bond head to position the first bond arm of the second bond head over a second bonding location within the first section of the substrate and to actuate just the first bond arm of the second bond head to place the first electronic device of the second group of electronic devices at the second bonding location within the first section of the substrate.

The apparatus may be operable to subsequently move the second bond head to position the second bond arm of the second bond head over a second bonding location within the second section of the substrate and to actuate only the second bond arm of the second bond head to place the second electronic device of the second group of electronic devices at the second bonding location within the second section of the substrate.

The apparatus may be operable to subsequently move the second bond head to position the third bond arm of the second bond head over a second bonding location within the third section of the substrate and to actuate only the third bond arm of the second bond head to place the third electronic device of the second group of electronic devices at the second bonding location within the third section of the substrate.

The apparatus may be operable to subsequently move the second bond head to position the fourth bond arm of the second bond head over a second bonding location within the fourth section of the substrate and to actuate only the fourth bond arm of the second bond head to place the fourth electronic device of the second group of electronic devices at the second bonding location within the fourth section of the substrate.

The first bond head and the second bond head may share a common positioning mechanism for positioning the first and second bond heads along orthogonal X and Y axes. The first and second bond heads may be movable together along the X axis but independently along the Y axis between different pickup and/or placement positions.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1 illustrates schematically a pick-and-place apparatus having a single bond head according to one embodiment;

FIGS. 2A and 2B illustrate schematically the configuration and operation of an individual bond arm in more detail;

FIGS. 3A to 3E illustrate schematically a pickup operation using the single bond head;

FIGS. 4A to 4E illustrate schematically a place operation using the single bond head;

FIG. 5 illustrates schematically a pick-and-place apparatus having dual bond heads according to one embodiment;

FIGS. 6A to 6I illustrate schematically a pickup operation;

FIGS. 7A to 7Q illustrate schematically a pick place operation using the dual bond heads;

FIGS. 8A to 8C illustrate schematically a placement operation; and

FIG. 9 illustrates schematically a pick-and-place apparatus having dual bond heads according to yet another embodiment.

In the drawings, like parts are denoted by like reference numerals.

### DETAILED DESCRIPTION

Before discussing embodiments, an overview will first be provided. Some embodiments provide an arrangement whereby a bond head is provided with a plurality of individually-moveable bond arms. A single bond arm may be extended at any one time to pick up single devices from a pickup location. This enables the bond arm to pick up multiple devices sequentially during the pickup operation, which can accommodate any difference in pitch between the bond arms and the devices. Also, picking up multiple devices during the pickup operation reduces the number of transfers between the pickup location and a bonding location, which improves the throughput of the apparatus. A single bond arm may be extended at any one time to place single devices at the bonding location. Again, this enables the bond arm to place multiple devices sequentially during the place operation which can accommodate any difference in pitch between the bond arms and the bonding locations. Some embodiments provide for a plurality of bond heads each with a plurality of individually-moveable bond arms. This enables simultaneous or concurrent pick-and-place operations, with one bond head picking up at the pickup location while another bond head places at the bonding location. Again, this improves the throughput of the apparatus.

### Pick-and-Place Apparatus—Single Bond Head

FIG. 1 illustrates schematically a pick-and-place apparatus 10, according to one embodiment. The pick-and-place apparatus 10 comprises a bond head 20. The bond head 20 comprises four individually displaceable bond arms 30A-D that are linearly arranged along the Y-axis direction adjacent to one another in a row. However, it will be appreciated that more than four bond arms may be provided or as few as two. Each bond arm 30A-D has a pickup end, wherein a vacuum collet may be located, and it is configured to pick up, retain and release an electronic device. Each bond arm 30A-D is retained on and individually displaceable along a Z-axis direction by its own actuator. The actuators are each coupled with a Z-axis motor 50. The Z-axis motor 50 is received on a Z-axis guide rail 60. The Z-axis guide rail 60 is coupled with a Y-axis motor 70. The Y-axis motor 70 is received on a Y-axis guide rail 80. The Y-axis guide rail 80 is coupled with an X-axis motor 90. The X-axis motor 90 is received on an X-axis guide rail 100. Hence, the bond head 20 is moveable along the X, Y and Z axes, while each bond arm 30A-D is individually displaceable along the Z axis.

The pick-and-place apparatus 10 is provided with a supply of electronic devices. In this example, the electronic devices electronic devices that are separated from a wafer 110 retained on an adhesive substrate on a wafer table positionable over a pickup station. However, it will be appreciated that other arrangements of electronic devices may be provided.

The pick-and-place apparatus 10 also comprises a bonding station 120 having a substrate 130 which in this example is a lead frame which has a number of lead frame pads located at different bonding locations 140. The substrate 130 is oriented with its length parallel to the Y axis.

### Bond Arm

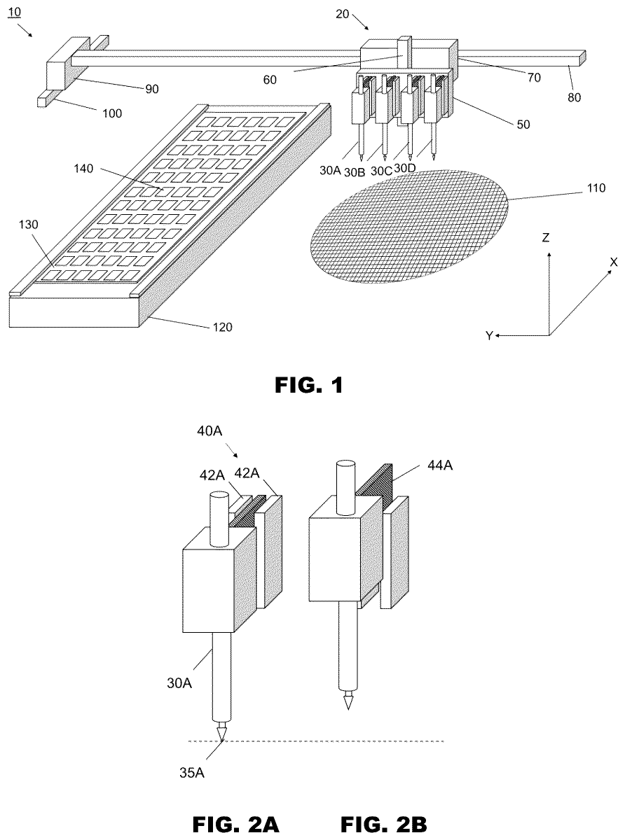

FIGS. 2A and 2B illustrate schematically the configuration and operation of an individual bond arm 30A in more detail. The actuator 40A is provided by a pair of magnets 42A placed on either side of a voice coil 44A. Passing a current through the voice coil 44A causes a displacement of the bond arm 30A along the Z-axis direction between an extended or lowered position in FIG. 2A and a retracted or raised position in FIG. 2B. This motion is important so that the bond arms will not touch an object on the pickup station or on the bonding station 120 while another bond arm is performing a picking or placing (bonding) process.

Hence, as can be seen, the entire bond head 20 is moveable along the X, Y and Z axes through operation of the motors 50, 70, 90 on their respective guide rails 60, 80, 100. Also, individual bond arms 30A-D are individually displaceable along the Z-axis direction between retracted and extended positions through operation of their actuators.

### Pickup Operation

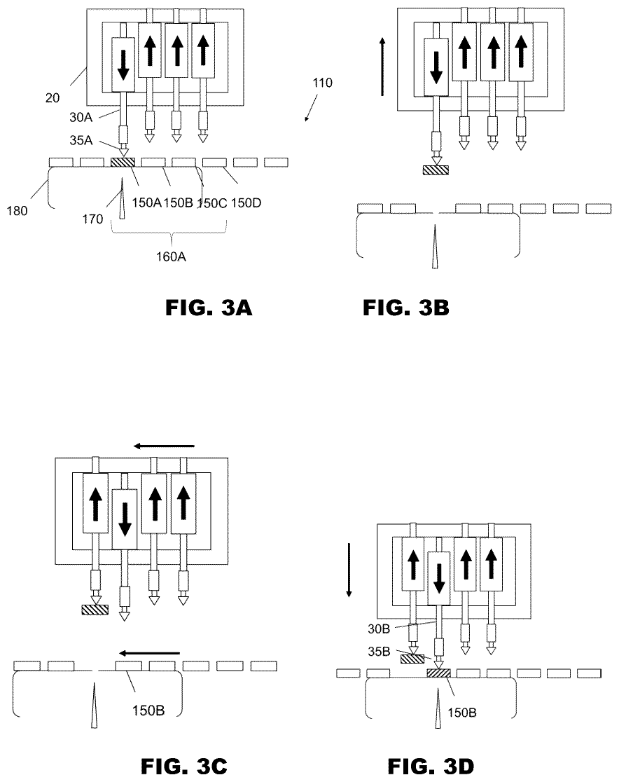

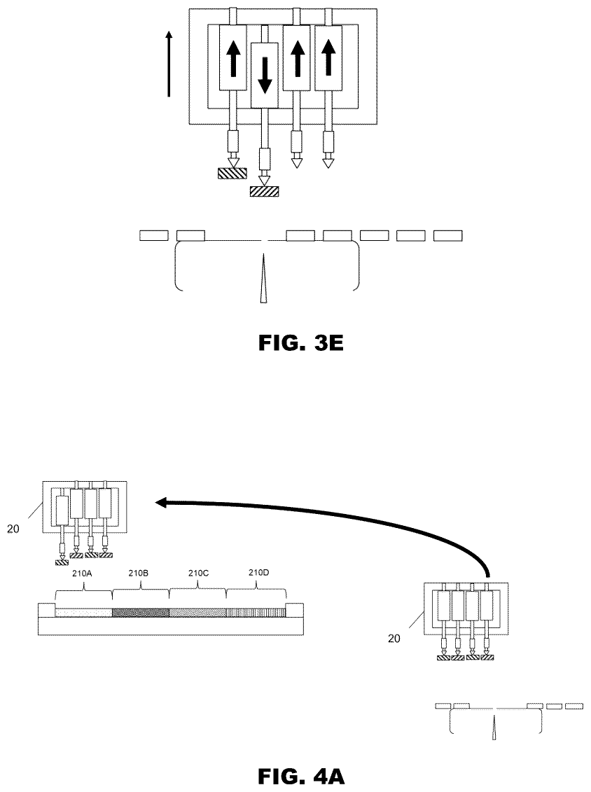

FIG. 3A illustrates schematically a pickup operation according to one embodiment. A first electronic device 150A of a first group of electronic devices 160 from the wafer 110 is placed over an ejector, which may be in the form of a pin ejector 170, at the pickup station 180 of the pick-and-place apparatus 10.

The first electronic device 150A is positioned over the pin ejector 170 and the bond head 20 is positioned over the first electronic device 150A. The bond arms 30B-D are in the retracted position whilst the bond arm 30A is in the extended position. The bond head 20 moves towards the first electronic device 150A along the Z axis. The pickup end 35A with the assistance of the pin ejector 170 picks up and retains the first electronic device 150A as the bond head 20 moves away from the pickup station 180, as illustrated in FIG. 3B.

As shown in FIG. 3C, the wafer 110 is moved with respect to the pickup station 180 to position a second electronic device 150B from the first group of electronic devices 160 over the pin ejector 170. The bond head 20 is moved so that the second bond arm 30B is positioned over the second electronic device 150B of the first group of electronic devices 160. As shown in FIG. 3D, the bond head 20 is lowered with only the second bond arm 30B in the extended position and the other bond arms 30A, 30C, 30D in the retracted position. The pickup end 35B of the second bond arm 30B then picks up the second electronic device 150B with the assistance of the pin ejector 170 as the bond head 20 is raised along the Z-axis, away from the pickup station 180, as illustrated in FIG. 3E.

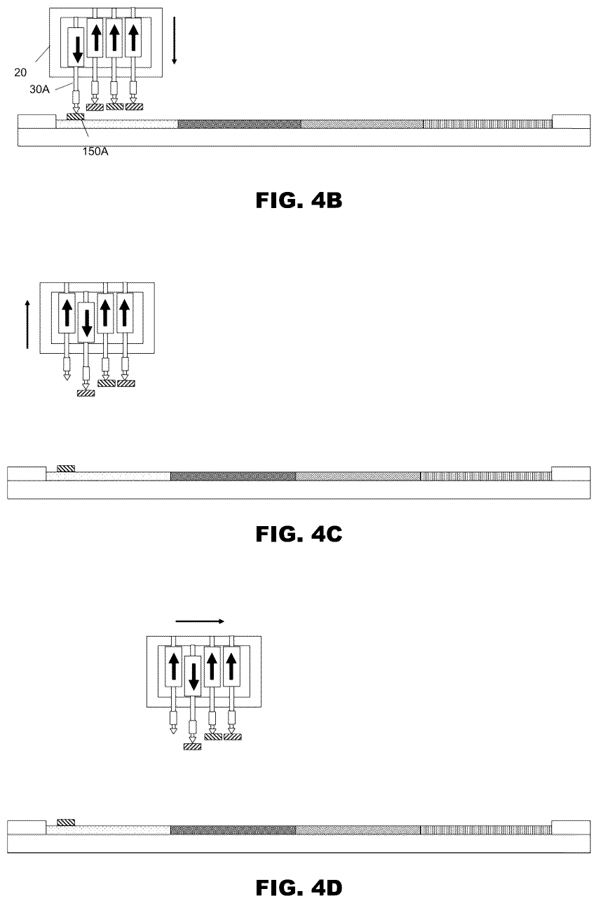

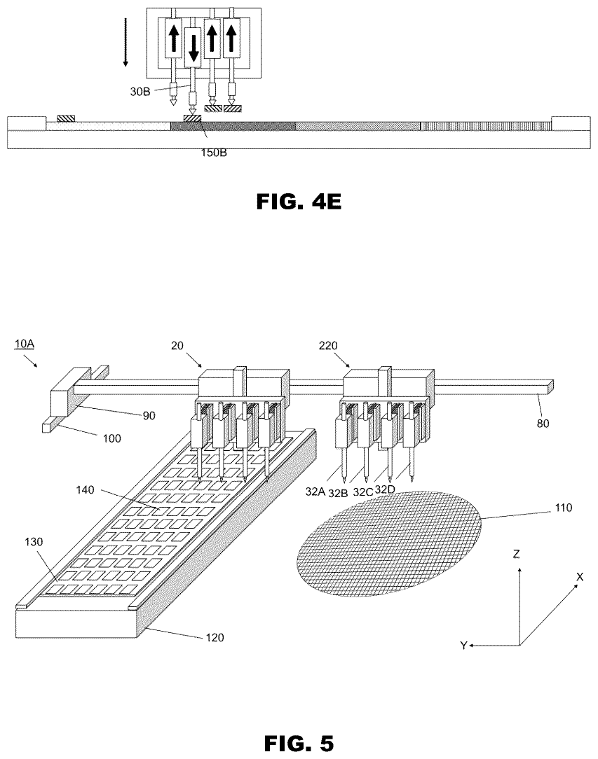

This process continues until each bond arm 30A-D has picked up an associated electronic device 150A-D from the first group of electronic devices 160, as shown in FIG. 4A. Although in this example the first group of electronic devices 160 comprises adjacent electronic devices, it will be appreciated that this need not be the case and that the first group of electronic devices 160 may comprise other than adjacent electronic devices.

### Placement Operation

Once each bond arm 30A-D has picked an associated electronic device 150A-D, the bond head 20 is repositioned by operating the Z-axis motor 50, the Y-axis motor 70 and the X-axis motor 90 over the bonding station 120. In particular, in this example, the bonding station 120 is split into four sections 210A-D. However, it will be appreciated that greater or fewer sections may be provided. The bond head 20 is positioned so that the bond arm 30A is positioned over a first bonding location in a first section 210A. As shown in FIG. 4A, only the first bond arm 30A is extended and the other bond arms 30B-D remain in the retracted position.

The bond head 20 is displaced along the Z-axis direction towards the bonding station 120 and the first electronic device 150A is placed at a first bonding location in the first section 210A, as shown in FIG. 4B.

As shown in FIG. 4C, the bond head 20 is raised along the Z axis away from the bonding station 120, the first bond arm 30A is retracted and only the second bond arm 30B is extended. The bond head 20 is positioned so that the second bond arm 30B is positioned over a first bonding location in the second section 210B, as shown in FIG. 4D.

As can be seen in FIG. 4E, the bond head 20 is moved along the Z-axis direction and the second electronic device 150B is placed at the first bonding location in the second section 210B. This process continues until each electronic device 150A-D has been placed at a first bonding location in each of the sections 210A-D.

The bond head 20 then returns to the pickup station 180 to pickup the next group of electronic devices in the next pickup operation before returning to the bonding station 120 and placing those electronic devices in each of the sections in a subsequent placement operation, and so on.

The placement locations are typically distributed into sections because, in terms of Y axis motion, it is more efficient to travel over a larger distance in a single direction, rather than having to keep tracking back in an opposite direction by small increments since the pitch between the bond arms is typically larger than the pitch between adjacent bonding locations. This does not result in a time penalty because time is also required for the up-down Z-axis motion that has to be conducted concurrently with the Y motion. Even if the Y distance is reduced, the time taken to travel over a larger Y distance is not more than the time taken to travel over the Z distance in either case, and the net result is about the same. Moreover, the bond arm still needs some time to stabilize notwithstanding the smaller distance travelled.

### Pick-and-Place Apparatus—Dual Bond Heads

FIG. 5 illustrates schematically a pick-and-place apparatus 10A, according to one embodiment which is similar to the arrangement shown in FIG. 1. However, the pick-and-place apparatus 10A in this embodiment comprises the bond head 20 as well as a second bond head 220. The arrangement of the second bond head 220 is the same as that of the bond head 20. The second bond head 220 comprises four individually displaceable bond arms 32A-D. It will be appreciated that more than four bond arms may be provided or as few as two. Each bond arm 32A-D has a pickup end, which may include a vacuum collet, configured to pick up, retain and release an electronic device. Each bond arm 32A-D is retained on and individually displaceable along a Z-axis direction by its own actuator. The actuators are each coupled with a Z-axis motor 50. The Z-axis motor is received on a Z-axis guide rail 60. The Z-axis guide rail 60 is coupled with a Y-axis motor 70. The Y-axis motor 70 is received on a Y-axis guide rail 80. The Y-axis guide rail 80 is coupled with an X-axis motor 90. The X-axis motor 90 is received on an X-axis guide rail 100. Hence, the second bond head 220 is moveable along the X, Y and Z axes and each bond arm 32A-D is individually displaceable along the Z axis. Accordingly, the bond arms 30A-D, 32A-D move together along the X axis but can move independently of each other along the Y and Z axes. Providing a second bond head 220 sharing the same Y-axis guide rail 80 helps to reduce an apparatus size while increasing throughput.

### Pickup Operation

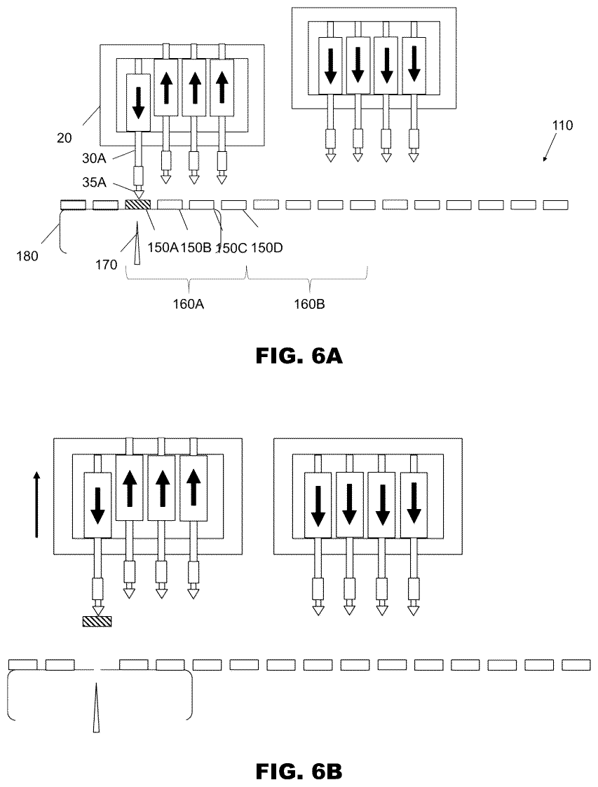

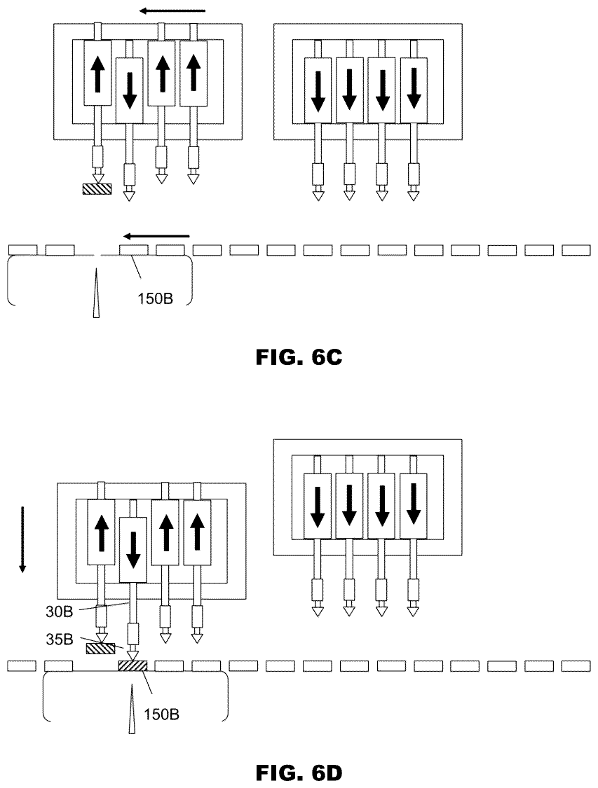

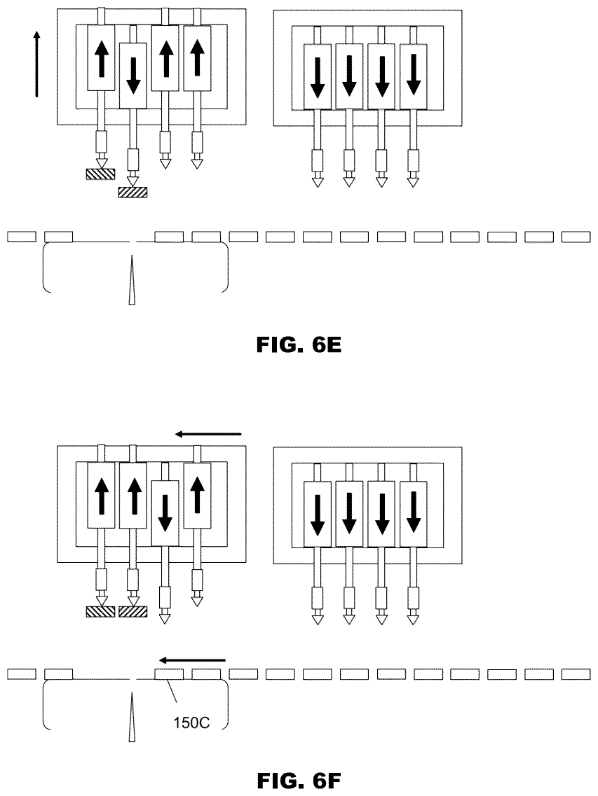

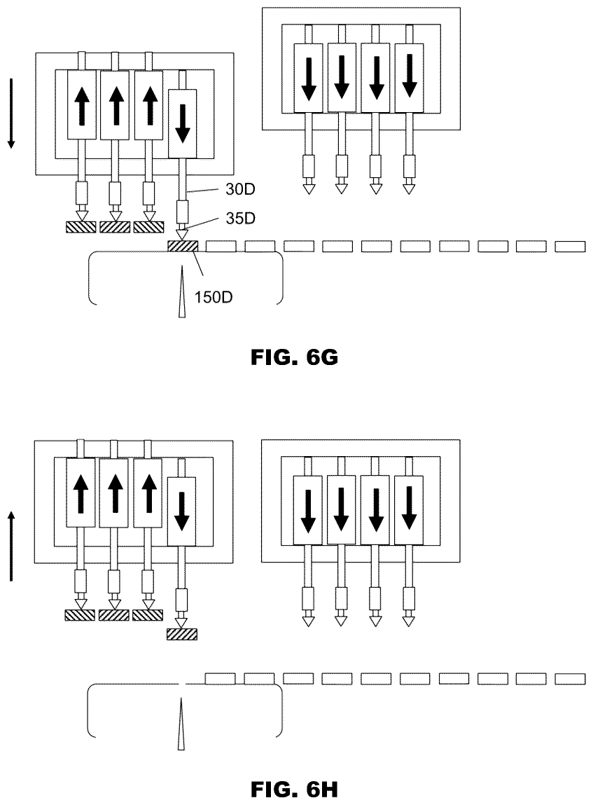

FIG. 6A illustrates schematically a pickup operation according to one embodiment. A first electronic device 150A of a first group of electronic devices 160A from the wafer 110 is positioned over a pin ejector 170 at the pickup station 180 of the pick-and-place apparatus 10A.

The first electronic device 150A is positioned over the pin ejector 170 and the bond head 20 is positioned over the first electronic device 150A. The bond arms 30B-D are in the retracted position whilst the first bond arm 30A is in the extended position. The bond head 20 moves towards the first electronic device 150A along the Z axis. The pickup end 35A picks up and retains the first electronic device 150A with the assistance of the pin ejector 170, before the bond head 20 moves away from the pickup station 180, as illustrated in FIG. 6B.

As shown in FIG. 6C, the wafer 110 is moved with respect to the pickup station 180 to position a second electronic device 150B from the first group of electronic devices 160 over the pin ejector 170. The bond head 20 is moved so that the second bond arm 30B is positioned over the second electronic device 150B of the first group of electronic devices 160A. As shown in FIG. 6D, the bond head 20 is lowered with only the second bond arm 30B in the extended position and the other bond arms 30A, 30C, 30D in the retracted position. The pickup end 35B of the second bond arm 30B then picks up the second electronic device 150B with the assistance of the pin ejector 170 before the bond head 20 is raised along the Z-axis direction, away from the pickup station 180, as illustrated in FIG. 6E.

This process continues as shown in FIGS. 6F to 6I until each bond arm 30A-D has picked up an associated electronic device 150A-D from the first group of electronic devices 160A, as shown in FIG. 4A. Although in this example the first group of electronic devices 160A comprises adjacent electronic devices, it will be appreciated that this need not be the case and that the first group of electronic devices 160 may comprise other than adjacent electronic devices.

### Pick and Place Operation

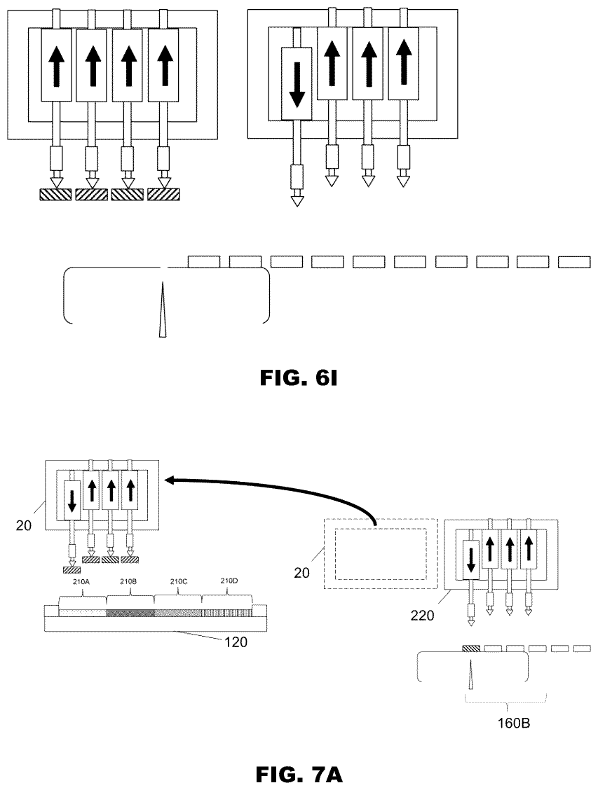

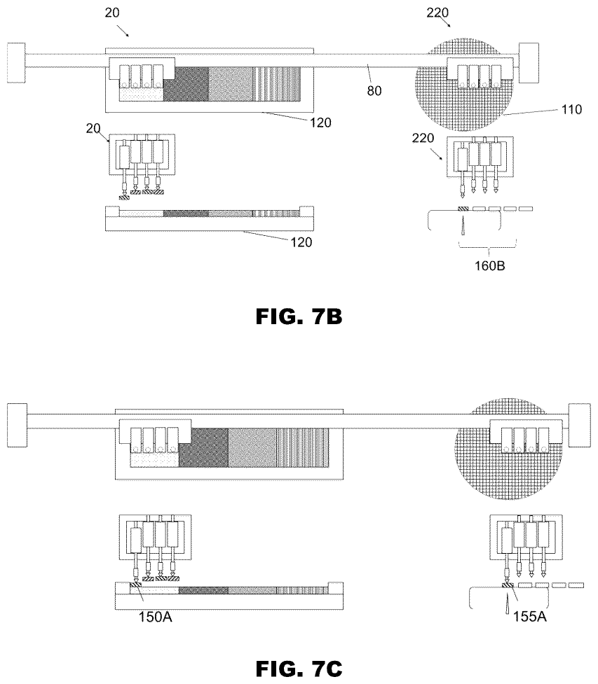

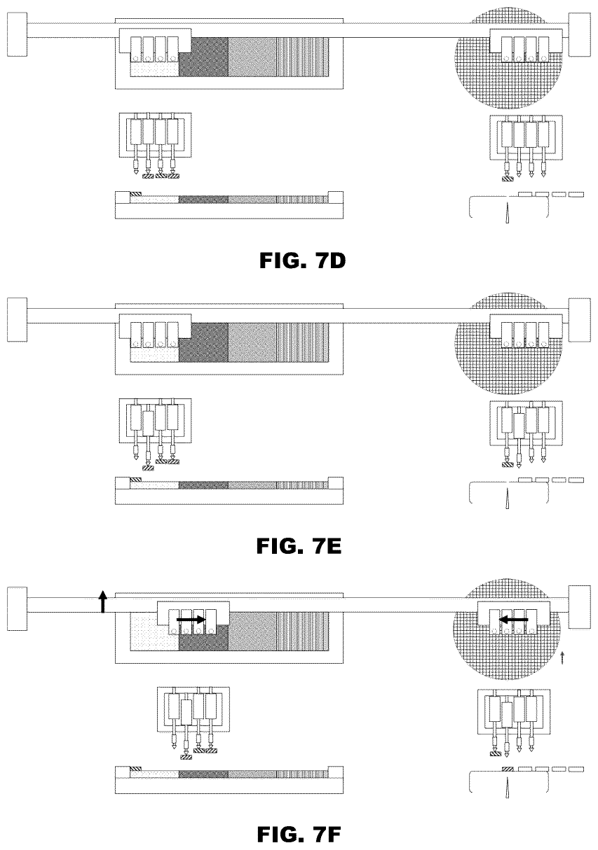

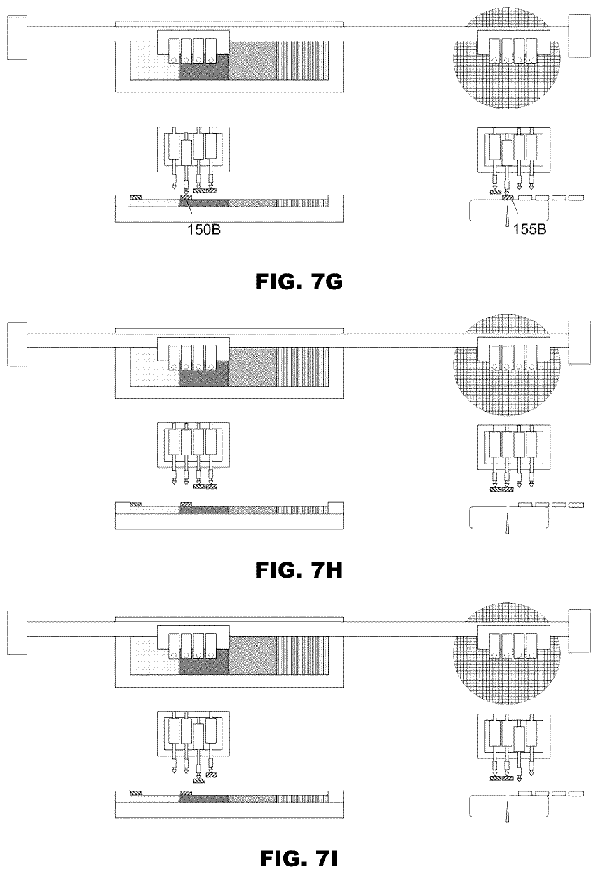

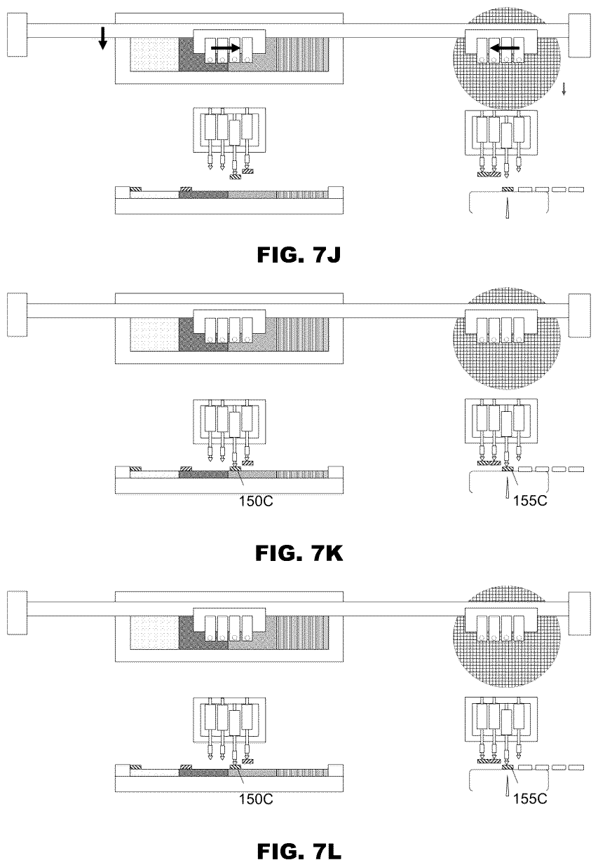

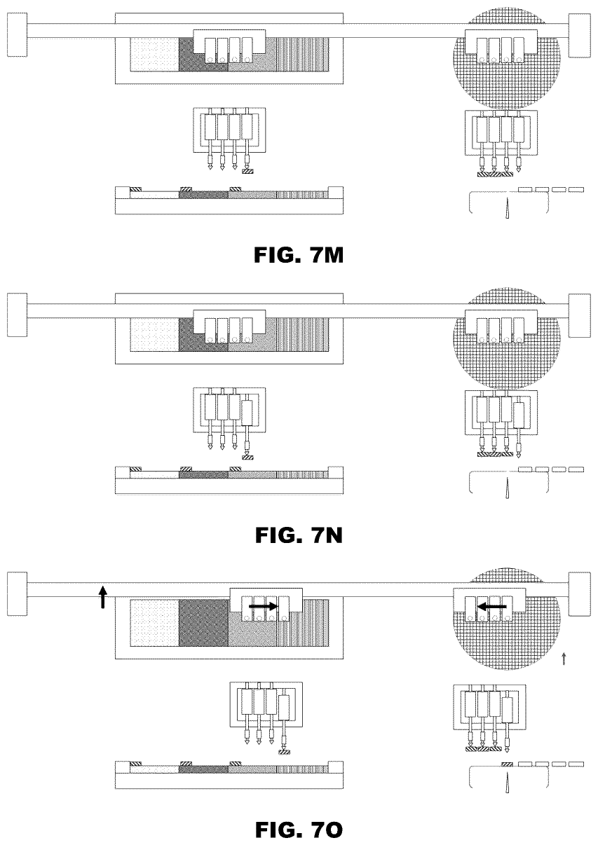

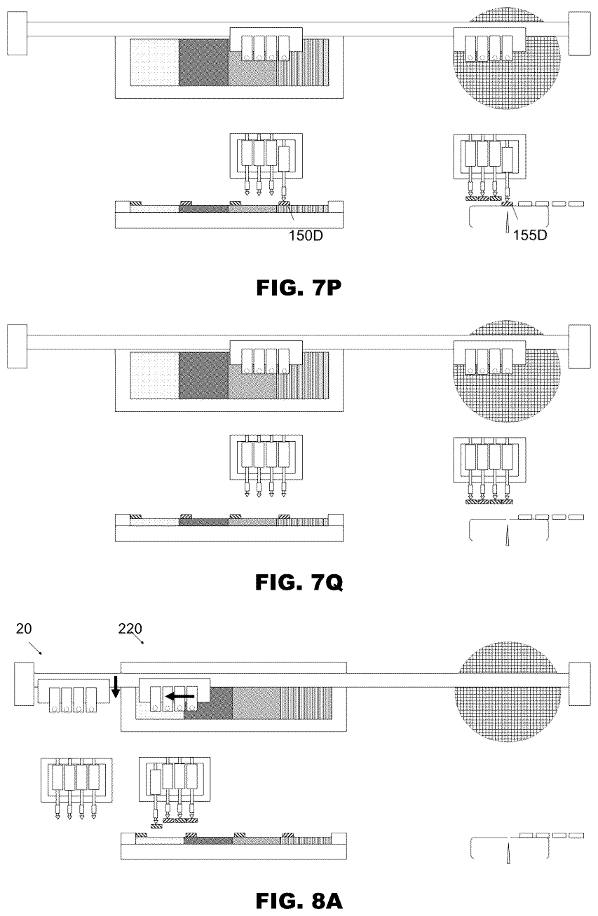

Once each bond arm 30A-D has picked up an associated electronic device 150A-D, the bond head 20 is repositioned by operating the Z-axis motor 50, the Y-axis motor 70 and the X-axis motor 90 over to the bonding station 120. In particular, in this example, the bonding station 120 is split into four sections 210A-D. The bond head 20 is positioned so that the bond arm 30A is positioned over a first bonding location in a first section 210A. As shown in FIG. 7A, only the first bond arm 30A is extended and the other bond arms 30B-D remain in the retracted position. Meanwhile, as shown in FIG. 7B (which shows a schematic plan view and schematic side view respectively of the operation of the pick-and-place apparatus 10A), the first electronic device 155A of the second group of electronic devices 160B is positioned over the pin ejector 170 and the second bond head 220 is positioned over the first electronic device 155A. The bond arms 32B-D are in the retracted position whilst the first bond arm 32A is in the extended position.

As shown in FIG. 7C, the second bond head 220 moves towards the first electronic device 150A along the Z axis. At the same time, the bond head 20 is displaced along the Z-axis direction towards the bonding station 120 and the first electronic device 150A is placed at a first bonding location in the first section 210A.

As shown in FIG. 7D, the pickup end of the bond arm 32A with the assistance of the pin ejector 170 picks up and retains the first electronic device 155A before the second bond head 220 moves away from the pickup station 180. At the same time, the bond head 20 is raised along the Z axis away from the bonding station 120 and the first bond arm 30A is retracted.

As shown in FIG. 7E, only the second bond arm 30B of the bond head 20 is extended and only the second bond arm 32B of the second bond head 220 is extended.

As shown in FIG. 7F, the bond head 20 is positioned so that the second bond arm 30B is positioned over a first bonding location in the second section 210B. Meanwhile, the wafer 110 is moved with respect to the pickup station 180 to position a second electronic device 155B from the second group of electronic devices 160B over the pin ejector 170. The second bond head 220 is moved so that the second bond arm 32B is positioned over the second electronic device 155B of the second group of electronic devices 160B. The second bond head 220 moves along the Y axis to align the pickup position for the second bond arm 32B. As the bond head 20 and the second bond head 220 share the same bond head X axis, indexing of the pin ejector 170 and wafer table will move accordingly for a compensated X location for the second bond arm 32B pick process. A similar operation happens in FIG. 7J.

As shown in FIG. 7G, the second bond head 20 is lowered with only the second bond arm 32B in the extended position and the other bond arms 32A, 32C, 32D in the retracted position. The second bond arm 32B then picks up the second electronic device 155B with the assistance of the pin ejector 170. Meanwhile, the bond head 20 is moved along the Z-axis direction and the second electronic device 150B is placed at the first bonding location in the second section 210B.

This process continues as shown in FIGS. 7H to 7Q until each electronic device 150A-D has been placed at a first bonding location in each of the sections 210A-D by the bond head 20 and each electronic device 155A-D has been picked up by the second bond head 220.

### Placement Operation

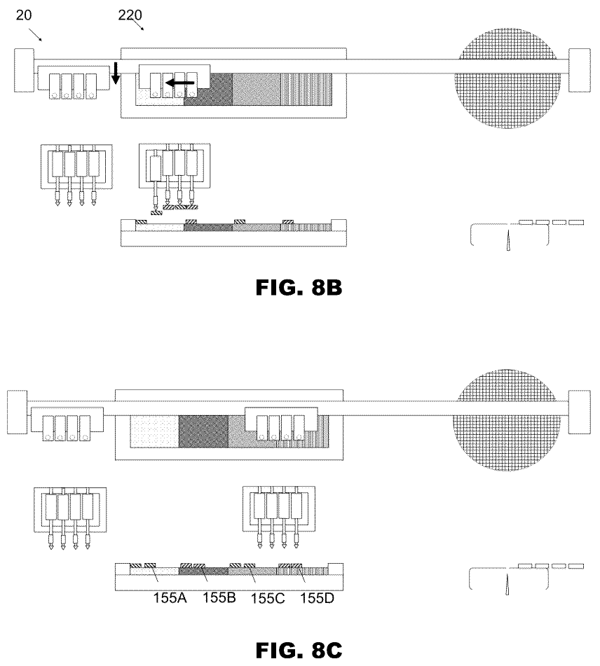

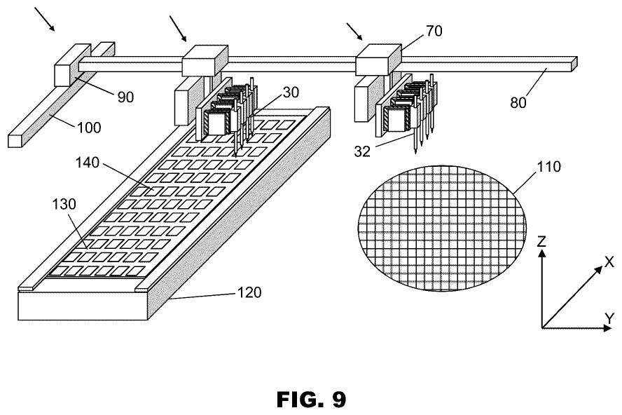

Once each bond arm 32A-D has picked an associated electronic device 155A-D, the bond head 20 is repositioned to one side of the bonding station 120. Meanwhile, the second bond head 220 is repositioned over the bonding station 120, as shown in FIG. 8A.

The second bond head 220 is positioned so that the first bond arm 32A is positioned over a second bonding location in the first section 210A. As shown in FIG. 8B, only the first bond arm 32A is extended and the other bond arms 32B-D remain in the retracted position.

The second bond head 20 is displaced along the Z-axis direction towards the bonding station 120 and the first electronic device 150A is placed at a second bonding location in the first section 210A.

This process continues until each electronic device 155A-D has been placed at a second bonding location in each of the sections 210A-D.

The bond head 20 and the second bond head 220 then return to the pickup station 180 to repeat the pickup operation for the next group of electronic devices, then repeating the pick-and-place operation and then repeating the placement operation mentioned above, and so on.

FIG. 9 illustrates schematically a pick-and-place apparatus 10C, according to yet another embodiment which is similar to the arrangement shown in FIG. 5. However, in the pick-and-place apparatus 10C of this embodiment, the bond arms of the bond head 20 as well as the second bond head 220 are linearly arranged along the X axis. This can be done by changing or replacing the bond heads 20, 220 mounted on the Y-axis motor 70. The replacement bond heads thus have bond arms 30A-D, 32A-D that are arranged along the X axis. In other words, the orientation of the bond arms 30A-D, 32A-D has effectively been rotated by a 90-degree angle. In this case, the substrate is arranged such that its length extends parallel to the X axis. However, it may also be advantageous (although not essential) for the substrate 130 to be rotated such that its length extends parallel to the Y axis, and the respective sections 210A-D would then similarly extend along the Y axis.

In this embodiment, the bond head 20 and second bond head 220 are moveable along the X, Y and Z axes and each bond arm 30A-D, 32A-D is individually displaceable along the Z axis. The respective bond arms 30A-D, 32A-D therefore move together along the X axis but can move independently of each other along the Y and Z axes. Since the pick-and-place operations are conducted in a similar way as that described in relation to FIG. 5 to successively pick up and/or place electronic devices 150, except that the bond arms 30A-D, 32A-D are oriented in the X-axis direction instead of the Y-axis direction, a detailed description of the individual processes will not be repeated here.

Hence, it can be seen that some embodiments provide for die transfer by a multiple bond arm module in single or dual bond head configurations. This arrangement increases the number of dies transferred and the overall output or throughput of the pick-and-place operations is increased. In particular, some embodiments integrate a multiple bond arm module into one head or two heads; a local Z motor is used to control up-down motion of a bond arm shaft. A parallel pick-and-place bonding process is implemented (one bond head is picking while another one is bonding) by the dual bond head mounted with quadruple or multiple bond arms.

Although the present invention has been described in considerable detail with reference to certain embodiments, other embodiments are possible.

Therefore, the spirit and scope of the appended claims should not be limited to the description of the embodiments contained herein.

1. A method of transferring a plurality of electronic devices with a bond head mechanism having a bond head having a plurality of individually-displaceable bond arms, comprising:
in a pickup operation, moving the bond head mechanism to position a first bond arm of the bond head mechanism over a first electronic device from a group of electronic devices from a supply of electronic devices arranged in a pickup area, and actuating only the first bond arm to pick up the first electronic device from the group of electronic devices; and
moving the bond head to position a second bond arm of the bond head over a second electronic device from the group of electronic devices, and actuating only the second bond arm of the bond head to pick up the second electronic device.

2. The method of claim 1, comprising, during the pickup operation, moving the bond head to position a third bond arm of the bond head over a third electronic device from the group of electronic devices, and actuating only the third bond arm of the bond head to pick up the third electronic device from the group of electronic devices.

3. The method of claim 2, comprising, during the pickup operation, moving the bond head to position a fourth bond arm of the bond head over a fourth electronic device from the group of electronic devices, and actuating only the fourth bond arm of the bond head to pick up the fourth electronic device from the group of electronic devices.

4. The method of claim 1, wherein each bond arm of the bond head comprises an individual actuator configured to displace that bond arm in directions towards and away from the group of electronic devices and the actuating comprises activating the individual actuator associated with that bond arm to displace only that bond arm towards the group of electronic devices to engage with a respective electronic device and then away from the group of electronic devices to pick up that electronic device.

5. The method of claim 4, wherein the actuating comprises activating the individual actuator associated with that bond arm to displace only that bond arm between a retracted position spaced from the group of electronic devices and an extended position in contact with the respective electronic device to be picked up.

6. The method of claim 1, comprising, during the pickup operation, sequentially moving the group of electronic devices to locate each electronic device from the group of electronic devices over an ejector pin and displacing the ejector pin to facilitate pickup of that electronic device by a respective bond arm.

7. The method of claim 1, wherein, during the pickup operation, the second bond arm of the bond head is adjacent the first bond arm of the bond head.

8. The method of claim 1, wherein, during the pickup operation, the second electronic device is adjacent the first electronic device in the group of electronic devices.

9. The method of claim 1, wherein, during the pickup operation, the first electronic device is arranged adjacent to the second electronic device along a row of electronic devices.

10. The method of claim 1, comprising, in a placement operation,
moving the bond head to position the first bond arm of the bond head over a bonding location within a first section of a substrate at a bonding station and actuating just the first bond arm of the bond head to place the first electronic device of the group of electronic devices at the bonding location within the first section of the substrate.

11. The method of claim 10, comprising, during the placement operation,
subsequently moving the bond head to position the second bond arm of the bond head over a bonding location within a second section of the substrate and actuating only the second bond arm of the bond head to place the second electronic device of the group of electronic devices at the bonding location within the second section of the substrate.

12. The method of claim 11, comprising, during the placement operation,
subsequently moving the bond head to position the third bond arm of the bond head over a bonding location within a third section of the substrate and actuating only the third bond arm of the bond head to place the third electronic device of the group of electronic devices at the bonding location within the third section of the substrate.

13. The method of claim 12, comprising, during the placement operation,
subsequently moving the bond head to position the fourth bond arm of the bond head over a bonding location within a fourth section of the substrate and actuating only the fourth bond arm of the bond head to place the fourth electronic device of the group of electronic devices at the bonding location within the fourth section of the substrate.

14. The method of claim 1, wherein the bond head comprises a first bond head and the bond head mechanism further comprises a second bond head separate from the first bond head, the second bond head having a plurality of individually-displaceable bond arms and wherein the group of electronic devices comprises a first group of electronic devices and wherein in a pick and place operation, the method further comprises:
moving the second bond head to position a first bond arm of the second bond head over a first electronic device from a second group of electronic devices and actuating only the first bond arm of the second bond head to pick up the first electronic device from the second group of electronic devices and
moving the first bond head to position the first bond arm of the first bond head over a first bonding location within a first section of a substrate at a bonding station, the substrate being divided into multiple sections of bonding locations, and actuating only the first bond arm of the first bond head to place the first electronic device from the first group of electronic devices at the first bonding location within the first section of the substrate.

15. The method of claim 14, comprising, during the pick and place operation,
subsequently moving the second bond head to position a second bond arm of the second bond head over a second electronic device from the second group of electronic devices and actuating only the second bond arm of the second bond head to pick up the second electronic device from the second group of electronic devices and
subsequently moving the first bond head to position the second bond arm of the first bond head over a first bonding location within a second section of the substrate and actuating only the second bond arm of the first bond head to place the second electronic device from the first group of electronic devices at the first bonding location within the second section of the substrate.

16. The method of claim 15, comprising, during the pick and place operation,
subsequently moving the second bond head to position a third bond arm of the second bond head over a third electronic device from the second group of electronic devices and actuating only the third bond arm of the second bond head to pick up the third electronic device from the second group of electronic devices and
subsequently moving the first bond head to position the third bond arm of the first bond head over a first bonding location within a third section of the substrate and actuating only the third bond arm of the first bond head to place the subsequent electronic device from the first group of electronic devices at the first bonding location within the third section of the substrate.

17. The method of claim 16, comprising, during the pick and place operation,
subsequently moving the second bond head to position a fourth bond arm of the second bond head over a fourth electronic device from the second group of electronic devices and actuating only the fourth bond arm of the second bond head to pick up the fourth electronic device from the second group of electronic devices and
subsequently moving the first bond head to position the fourth bond arm of the first bond head over a first bonding location within a fourth section of the substrate and actuating only the fourth bond arm of the first bond head to place the fourth electronic device from the first group of electronic devices at the first bonding location within the fourth section of the substrate.

18. The method of claim 14, wherein each pickup with the second bond head occurs simultaneously with each placement with the first bond head.

19. The method of claim 14, wherein, during the pick and place operation, the second bond arm of the second bond head is adjacent the first bond arm of the second bond head.

20. The method of claim 14, wherein, during the pick and place operation, the second electronic device of the second group of electronic devices is adjacent the first electronic device of the second group of electronic devices.

21. The method of claim 14, wherein, during the pick and place operation, successive sections of the substrate are contiguous with each other.

22. The method of claim 14, wherein, during the pick and place operation, each subsequent section containing bonding locations is adjacent a preceding section containing bonding locations.

23. The method of claim 14, comprising, in a placement operation,
moving the second bond head to position the first bond arm of the second bond head over a second bonding location within the first section of the substrate and actuating just the first bond arm of the second bond head to place the first electronic device of the second group of electronic devices at the second bonding location within the first section of the substrate.

24. The method of claim 23, comprising, during the placement operation,
subsequently moving the second bond head to position the second bond arm of the second bond head over a second bonding location within the second section of the substrate and actuating only the second bond arm of the second bond head to place the second electronic device of the second group of electronic devices at the second bonding location within the second section of the substrate.

25. The method of claim 24, comprising, during the placement operation,
subsequently moving the second bond head to position the third bond arm of the second bond head over a second bonding location within the third section of the substrate and actuating only the third bond arm of the second bond head to place the third electronic device of the second group of electronic devices at the second bonding location within the third section of the substrate.

26. The method of claim 25, comprising, during the placement operation,
subsequently moving the second bond head to position the fourth bond arm of the second bond head over a second bonding location within the fourth section of the substrate and actuating only the fourth bond arm of the second bond head to place the fourth electronic device of the second group of electronic devices at the second bonding location within the fourth section of the substrate.

27. The method of claim 14, wherein the first bond head and the second bond head share a common positioning mechanism for positioning the first and second bond heads along orthogonal X and Y axes, the first and second bond heads being movable together along the X axis but independently along the Y axis between different pickup and/or placement positions.

28. An apparatus for transferring a plurality of electronic devices, comprising:
a bond head mechanism having a plurality of individually-displaceable bond arms, the apparatus being operable in a pickup operation to position a first bond arm of the plurality of individually-displaceable bond arms over a first electronic device from a group of electronic devices in a pickup area and to actuate only the first bond arm to pick up the first electronic device from the group of electronic devices and to position a second bond arm of the plurality of individually-displaceable bond arms over a second electronic device from the group of electronic devices and to actuate only the second bond arm to pick up the second electronic device from the group of electronic devices.
